(19) United States
(12) Patent Application Publication
(10) Pub. No.: US 2009/0228762 A1
(43) Pub. Date: Sep. 10, 2009

(54) Inforamtion Precessing Apparatus and Non-Volatile Semiconductor Memory Drive

(75) Inventor: Takehiko Kurashige, Ome-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/391,110

(22) Filed: Feb. 23, 2009

Related U.S. Application Data
(63) Continuation of application No. PCT/JP2008/071179, filed on Mar. 7, 2008.

(30) Foreign Application Priority Data
Mar. 7, 2008 (JP) 2008-058545

(51) Int. Cl. G06F 11/00; G11C 29/00; G06F 11/14

(52) U.S. Cl. 714/764; 714/E11.056; 714/E11.113

(57) ABSTRACT

According to one embodiment, an information processing apparatus includes a main body and a memory drive which is accommodated in the main body. The main body includes a main control module which receives information including errors and error correction codes for correcting the errors from the memory drive, corrects the errors by using the error correction codes, and returns corrected information to the memory drive. The memory drive includes a memory control module which controls execution of first error correction processing which corrects errors for each sector and second error correction processing which corrects errors for each cluster, transmits information including the errors and error correction codes for correcting the errors to the main body when errors which cannot be corrected by the first and the second error correction processing have occurred, and updates the information including the errors in the corrected information returned from the main body.

### CROSS-REFERENCE TO RELATED APPLICATIONS

This is a Continuation Application of PCT Application No. PCT/JP2008/071179, filed Nov. 14, 2008, which was published under PCT Article 21(2) in English.

This application is based upon and claims the benefit of priority from Japanese Patent Application No. 2008-058545, filed Mar. 7, 2008, the entire contents of which are incorporated herein by reference.

### BACKGROUND

1. Field

One embodiment of the invention relates to an information processing apparatus and a non-volatile semiconductor memory drive.

2. Description of the Related Art

As regards a conventional technique, a memory data protection system for writing information encoded by an error correction code to a non-volatile memory, and for writing information added the error correction code in an unused area of the non-volatile memory has been known (e.g., Jpn. Pat. Appln. KOKAI Publication No. 2004-5062).

This memory data protection system periodically writes and reads information for the entire area of the non-volatile memory to detect errors, and records error occurrence information. Since the memory data protection system does not write the information in areas in which errors have occurred in accordance with the error occurrence information, may continuously use the non-volatile memory having areas with the errors have occurred therein without discarding the non-volatile memory.

Meanwhile, error correction processing to be performed by the non-volatile semiconductor memory drive itself by using the error correction code may be usable only for relatively insignificant errors. Recently, various error correction processing methods capable of applying advanced error correction processing by using this error correction code have been developed. Therefore, providing an interface for error correction to and from an information processing apparatus that is a host capable of applying this advanced error correction processing makes it possible to improve reliability and a product lifetime.

The invention has been made in consideration of the above, and an object of the invention is to provide an information processing apparatus and a non-volatile semiconductor memory drive for improving reliability and a product lifetime.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view showing an external appearance of an information processing apparatus according to an embodiment of the invention;

FIG. 2 is an exemplary block diagram showing a schematic configuration of the information processing apparatus according to the embodiment;

FIG. 3 is an exemplary block diagram showing a schematic configuration of a solid sate drive (SSD) according to the embodiment;

FIG. 4 is an exemplary schematic view showing storage capacities and storage areas of the SSD according to the embodiment;

FIG. 5 is an exemplary schematic view of a NAND memory according to the embodiment;

FIG. 6 is an exemplary schematic configuration view of a BCT of the information processing apparatus according to the embodiment;

FIG. 7 is an exemplary schematic configuration view of a file system driver of the information processing apparatus according to the embodiment;

FIG. 8 is an exemplary schematic view of a product lifetime of the SSD according to the embodiment;

FIGS. 9A and 9B are exemplary flowcharts relevant to online correction operations according to the embodiment; and

FIGS. 10A and 10B are n exemplary flowcharts relevant to online correction operations according to the embodiment.

### DETAILED DESCRIPTION

Various embodiments according to the invention will be described hereinafter with reference to the accompanying drawings. In general, according to one embodiment of the invention, an information processing apparatus includes an information processing apparatus main body and a non-volatile semiconductor memory drive which is accommodated in the information processing apparatus main body. The information processing apparatus main body includes a main control module which receives information including errors and error correction codes for correcting the errors included in the information from the non-volatile semiconductor memory drive, corrects the errors included in the information by using the error correction codes, and returns corrected information to the non-volatile semiconductor memory drive. The non-volatile semiconductor memory drive includes a non-volatile semiconductor memory including a plurality of storage areas where information is writable and information is readable, and a memory control module which controls execution of first error correction processing which corrects errors of the information stored in the storage areas for each sector and second error correction processing which corrects errors of the information stored in the storage areas for each cluster, transmits information including the errors and error correction codes for correcting the errors included in the information to the information processing apparatus main body when errors which cannot be corrected by the first and the second error correction processing have occurred, and updates the information including the errors stored in the storage areas in the corrected information returned from the information processing apparatus main body.

(Configuration of Information Processing Apparatus)

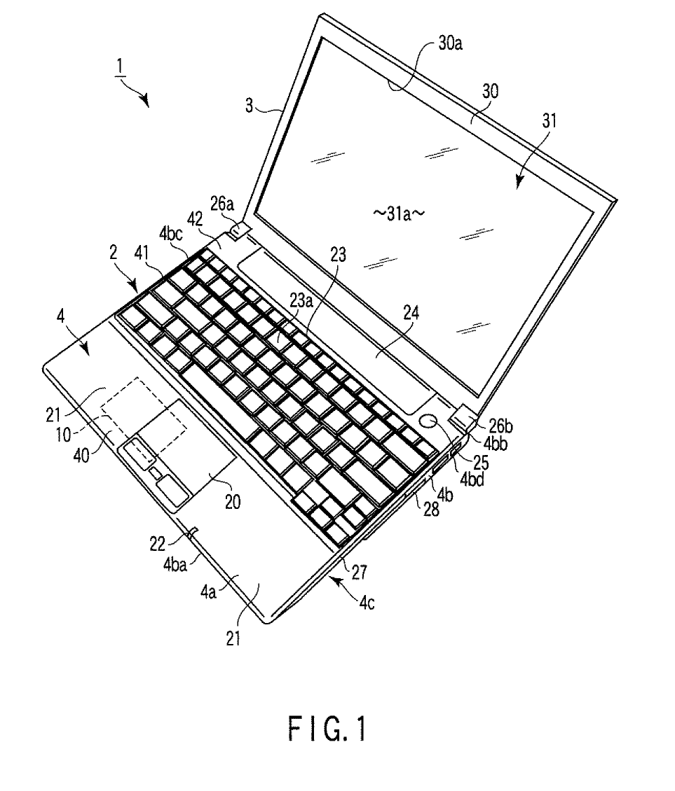

FIG. 1 is an exemplary perspective view showing an external appearance of an information processing apparatus 1 according to an embodiment of the invention. The information processing apparatus 1 is composed of a main body 2, and a display unit 3 attached to the main body 2, as shown in FIG. 1.

The main body 2 has a box-shaped housing 4, and the housing 4 includes a top wall 4a, a peripheral wall 4b and a bottom wall 4c. The top wall 4a of the housing 4 includes a front part 40, a central part 41 and a back part 42 which are arranged in order from a side close to a user who operates the information processing apparatus 1. The bottom wall 4c faces an installation surface on which the information processing apparatus 1 is placed. The peripheral wall 4b includes a front wall 4ba, a rear wall 4bb, and left and right sidewalls 4bc, 4bd.

The front part 40 includes a touch pad 20 which is a pointing device, a palm rest 21, and a liquid crystal display (LED) 22 which illuminates in conjunction with an operation of each of the components of the information processing apparatus 1.

The central part 41 includes a keyboard mounting part 23 on which a keyboard 23a capable of inputting character information, etc., is mounted.

The back part 42 includes a battery pack 24 which is detachably attached, a power switch 25 for turning on the power of the information processing apparatus 1 on the right side of the battery pack 24, and a pair of hinge portions 26a, 26b which rotatably supports the display unit 3 at the right and left sides of the battery pack 24.

An exhaust port (not shown) for exhausting wind from inside of the housing 4 to the outside thereof is disposed on the left sidewall 4bc of the housing 4. An optical disc drive (ODD) 27 capable of reading/writing data from/to an optical storage medium such as a DVD, and a card slot 28 in/from which various cards can be inserted/removed are disposed on the right sidewall 4bd.

The housing 4 is formed of a housing cover including a part of the peripheral wall 4b and the top wall 4a, and a housing base including a part of the peripheral wall 4b and the bottom wall 4c. The housing cover is detachably coupled to the housing base to form a housing space along with the housing base. The housing space houses a solid state drive (SSD) 10, etc., as a non-volatile semiconductor memory drive. Detail of the SSD 10 will be described later.

The display unit 3 includes a display housing 30 including an opening 30a and a display device 31 composed of an LCD, etc., capable of displaying images on a display 31a. The display device 31 is housed in the display housing 30, and the display 31a is exposed to the outside of the display housing 30 through the opening 30a.

In the housing 4, a main circuit board, an expansion module, a fan, etc., not shown, are housed, as well as the SSD 10, the battery pack 24, the ODD 27 and the card slot 28.

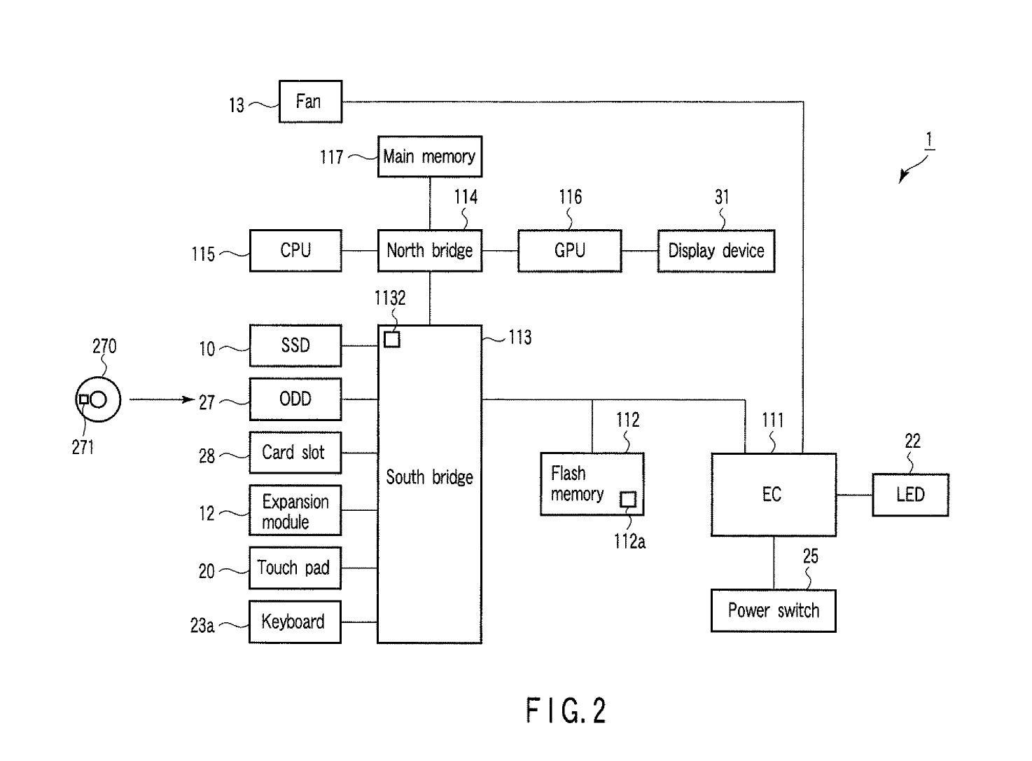

FIG. 2 is an exemplary block diagram showing a schematic configuration of the information processing apparatus 1 according to the embodiment of the invention.

The information processing apparatus 1 includes, as shown in FIG. 2, an embedded controller (EC) 111 which is an embedded system for controlling each component, a flash memory 112 which stores a basic input/output system (BIOS) 112a, a south bridge 113 which is a large scale integration (LSI) chip and functions as various bus controllers and as an I/O controller, a north bridge 114, which is an LSI chip, for controlling connections among a central processing unit (CPU) 115 to be described later, a graphic processing unit (GPU) 116, a main memory 117 and various buses, a CPU 115 as a main control unit for computing various signals, a GPU 116 which controls and computes video signals for display, and a main memory 117 read and written by the CPU 115, as well as the SSD 10, the expansion module 12, the fan 13, the touch pad 20, the LED 22, the keyboard 23a, the power switch 25, the ODD 27, the card slot 28 and display device 31.

While a refresh tool 271 which is an application for performing error correction processing is stored in an optical medium (storage medium) 271, the place where the refresh tool 271 to be stored is not limited to optical medium 271, and the refresh tool 271 may be stored in a storage medium which is readable from the card slot 28 or the expansion module 12.

The expansion module 12 includes an expansion circuit board, a card socket mounted on the expansion circuit board, an expansion module board inserted in the card socket. The card socket is based on the standards of Mini-PCI, etc., and the expansion module board may be a third generation (3G) module, a television tuner, a GSP module and a Wimax (trademark) module.

The fan 13 is a cooling unit which cools the inside of the housing 4 by means of ventilation, and exhausts the air in the housing 4 to the outsides via the exhaust port (not shown).

The EC 111, the flash memory 112, the south bridge 113, the north bridge 114, the CPU 115, the GPU 116 and the main memory 117 are the electronic components mounted on the main circuit board.

(Configuration of SSD)

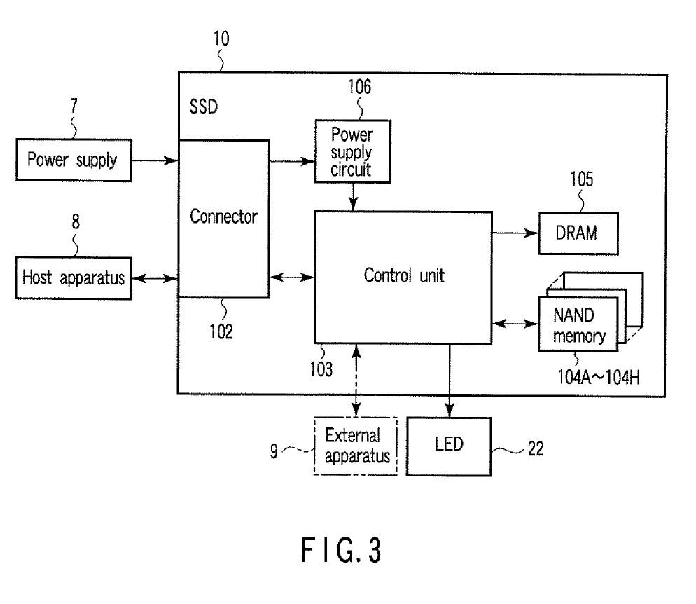

FIG. 3 is an exemplary block diagram showing a schematic configuration of the SSD 10 according to the embodiment of the invention. The SSD 10 is schematically formed of a connector 102, a control unit 103, NAND memories 104A-104H, a DRAM 105, and a power supply circuit 106, as shown in FIG. 3. The SSD 10 is an external storage device which stores data and programs and from which records are not lost even if the power is not supplied thereto. Although the SSD 10 has no drive mechanism such as a magnetic disk or a head like a conventional hard disk drive, the SSD 10 stores program such as an operating system (OS), data generated by a user or executing software, etc., readably and secularly in the storage areas of the NAND memories in the same way as that of the hard disk drive, and is a drive composed of a non-volatile semiconductor memory capable of operating as a boot drive of the information processing apparatus 1.

The control unit 103 as a memory controller is connected to each of the connector 102, the eight NAND memories 104A-104H, the DRAM 105 and the power supply circuit 106. The control unit 103 is connected to a host apparatus 8 via the connector 102, and is connected to the external apparatus, as necessary.

A power supply 7 is a battery pack 24 or an AC adapter, not shown, and 3.3 V DC is supplied to the power supply circuit 106 via the connector 102, for example. Further, the power supply 7 supplies power to the entirety of the information processing apparatus 1.

The host apparatus 8 is a main circuit board, in this embodiment, and the south bridge 113 mounted on the main circuit board is connected to the control unit 103. Data is transmission is made between the south bridge 113 and the control unit 103 based on the standard of a serial ATA, for example.

The external apparatus 9 is an information processing apparatus differing from the information processing apparatus 1. With respect to the SSD 10 detached from the information processing apparatus 1, the external apparatus 9 is connected to the control unit 103 based on standard of an RS-23C, for example, and has a function of reading data stored in the NAND memories 104A-104H.

The board on which the SSD 10 is mounted has, for example, the same outer shape and size as that of a hard disk drive (HDD) of a 1.8-inch type or a 2.5-inch type. In this embodiment, the outer shape and size is the same as that of the 1.8-inch type.

The control unit 103 controls operations of the NAND memories 104A-104H. More specifically, the control unit 103 controls reading/writing of data from/to the NAND memories 104A-104H in response to a request from the host apparatus 8. The data transmission speed is 100 MB/sec in data reading and 40 MB/sec in data writing, for example.

Each of the NAND memories 104A-104H is, for example, a non-volatile semiconductor memory with 16 GB as a storage capacity, and is, for example, a multi level cell (MLC)-NAND memory (multi-value NAND memory) capable of 2-bit recording in one memory cell. The MLC-NAND memory generally has no advantage over rewritable times as compared with a single level cell (SLC)-NAND memory, but the storage capacity can be easily increased.

The DRAM 105 is a buffer in which the data is temporarily stored at the time of data reading/writing from/to the NAND memories 104A-104H according to control of the control unit 103.

The connector 102 has a shape based on the standards such as a serial ATA. The control unit 103 and the power supply circuit 106 may be connected to the host apparatus 8 and the power supply 7, respectively, via different connectors.

The power supply circuit 106 converts 3.3 V DC supplied from the power supply 7 to 1.8 V, 1.2 V DC, for example, and supplies the three kinds of voltages to each component of the SSD 10.

(Storage Capacity of SSD)

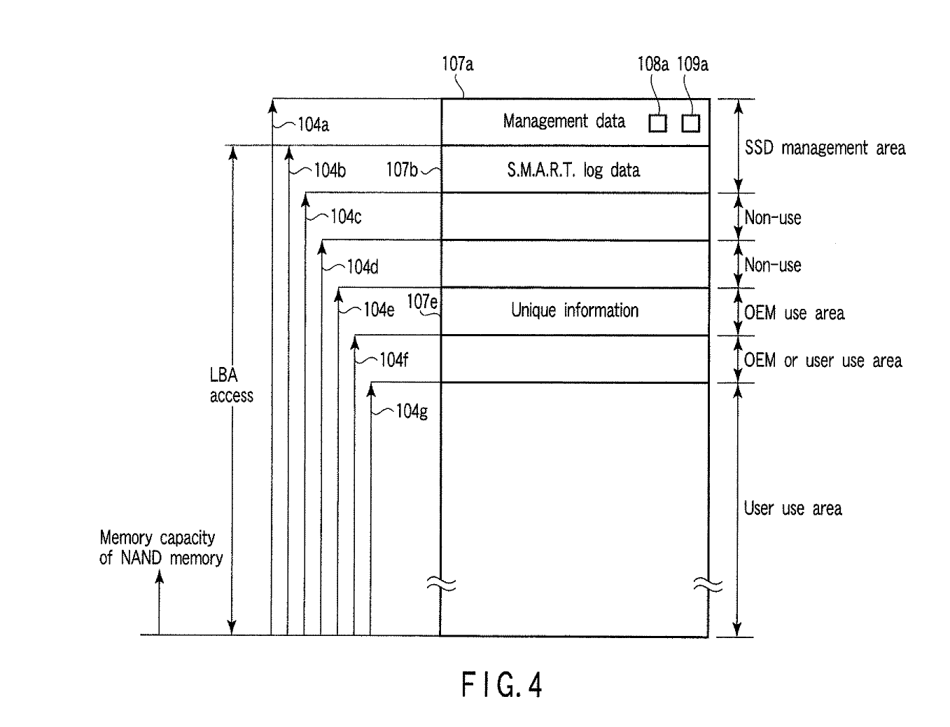

FIG. 4 schematically shows storage capacities and storage areas of the SSD 10 according to the embodiment of the invention. The storage capacity of the SSD 10 is formed of storage capacities 104a-104g as shown in FIG. 4.

The storage capacity 104a is a NAND Capacity, i.e., the maximum storage capacity using the storage areas of all the NAND memories 104A-104H. For instance, when the storage capacity of each of the NAND memories 104A-104H is 16 GB, the storage capacity 104a is 128 GB. The storage capacity 104a is given by NAND configuration information of a manufacturing information writing command of a universal asynchronous receiver transmitter (UART).

The storage capacity 104b is a Max Logical Capacity, and is the maximum storage capacity accessible by logical block addressing (LBA).

LBA means a system in which serial numbers are assigned to all sectors in the SSD 10 given below, and specifies the sectors by means of the serial numbers.

The storage capacity 104c is a self-monitoring analysis and reporting technology (S.M.A.R.T.) log area start LBA, and is provided for dividing the storage capacity 104b and the storage capacity 104d which will be described later. The detail will be described later.

The storage capacity 104d is a Vender Native Capacity, and is the maximum storage capacity given as a user use area. The storage capacity 104d is given by an initial Identify Device data of an ATM special command. The storage capacity 104d is determined by the vendor at a design stage of the SSD 10 based on the International Disk Drive Equipment and Memory Association (IDEMA) standards, and is expressed by the following Equation 1:

LBA=97,696,368+(1,953,504×((Capacity in GB)−50)) Equation 1

The storage capacity 104e is an original equipment manufacture (OEM) Native Capacity, and is the storage capacity determined at the time of manufacturing in response to a request from the OEM. The storage capacity 104e is given by writing unique information of an ATM specific command. The storage capacity 104e is a value returned by a Device Configuration Identify command when a Device Configuration Overlay Feature Set is supported.

The storage capacity 104f is a Native Capacity, and its initial value is the same value as the storage capacity 104e. The storage capacity 104f is a value which can be changed by a Device Configuration Set command when a Feature Set is supported. Further, the storage capacity 104f is a value returned by a Read Native Max Address (EXT) command.

The storage capacity 104g is a Current Capacity, and is the storage capacity during use by the user. The initial value of the storage capacity 104g is the same value as the storage capacity 104f. The storage capacity 104g can be changed by a Set Max Address command. The value is returned by Word 61:60 and Word 103:100 of an Identify Device command.

The storage areas of the SSD 10 exist between adjacent ones of the storage capacities 104a-104g.

In a storage area between the storage capacities 104a and 104b, a management data 107a for operating the SSD 10, a logical/physical table 108a for converting a logical address of data converted from the LBA into physical addresses corresponding to a sector which is a storage unit of the NAND memories 104A-104H and a bad cluster table (BAT) 109a mentioned later are stored. The management data 107a, the logical/physical table 108a and ECT 109a are data which cannot be accessed by using the LBA as a key, and is recorded, by using a fixed access path, in a fixed area in the NAND memories 104A-104H.

In a storage area between the storage capacities 104b and 104c, S.M.A.R.T. log data 107b which is statistics information of the foregoing temperature information, for example, is stored. The S.M.A.R.T. log data 107b is accessed by using the LBA as a key in being recorded an inside of firmware (FW), and is not be accessed by an ordinary Read command or a Write command from the host apparatus 8.

The firmware (FW) means software which is installed in the SSD 10 so as to control the SSD 10.

In a storage area between the storage capacities 104c and 104d, a non-used storage area having a storage capacity of 2 MB is set, for example. This is in order to handle the S.M.A.R.T. log data 107b and the data recorded in the storage capacity 104d or latter independently by providing a free storage area having a storage capacity of more than 1 MB, since a minimum storage unit of actual data is naturally 1 sector while a minimum storage unit of the LBA is 8sectors and is the storage unit corresponding to 4 KB (a large storage unit is 1 MB).

A storage area between the storage capacities 104d and 104e is unused and both the storage capacities have the same value except special cases.

A storage area between the storage capacities 104e and 104f is a storage area used by the OEM, and the unique information 107e determined by a request from the OEM is written as mentioned above.

A storage area between the storage capacities 104f and 104g is a storage area used by the OEM or the user, and data is written therein by setting by the OEM or user.

A storage area of the storage capacity 104g is a storage area used by the user, and data is written therein by setting by the user.

A storage capacities 104a-104g satisfy the relationship expressed by the following Equation 2:

Storage capacity 104a>storage capacity 104b>storage capacity 104c>storage capacity 104d>=storage capacity 104e>=storage capacity 104f>=storage capacity 104g Equation 2

At the time of shipping from a vender, the storage capacities 104d-104g are the same values.

(Configuration of NAND Memory)

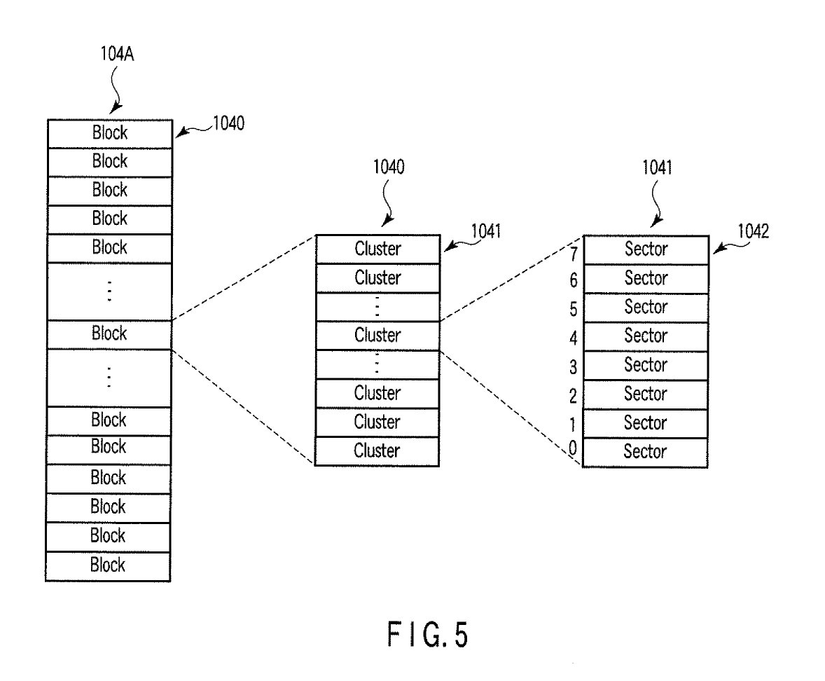

FIG. 5 shows a schematic configuration of a NAND memory according to the embodiment of the invention. Since the NAND memories 104A-104H each have the same function and configuration, an explanation will be made only about the NAND memory 104A.

The NAND memory 104A is composed of a plurality of blocks 1040. Each of the blocks 1040 is composed of 1024 clusters 1041, and each of the cluster 1041 is further composed of 8 sectors 1042.

For writing data less than the size of the block 1041, the control unit 103 of the SDD 10 reads the 1024 clusters 1041 composed of the block 1040 on the basis of the management data 107a, temporary stores the read data in the DRAM 105, writes the data to the cluster 1041 in which the data has been read from the DRAM 105, and writes the data to the cluster 1041 in the relevant NAND memory from the DRAM 105.

(Configuration OF BCT)

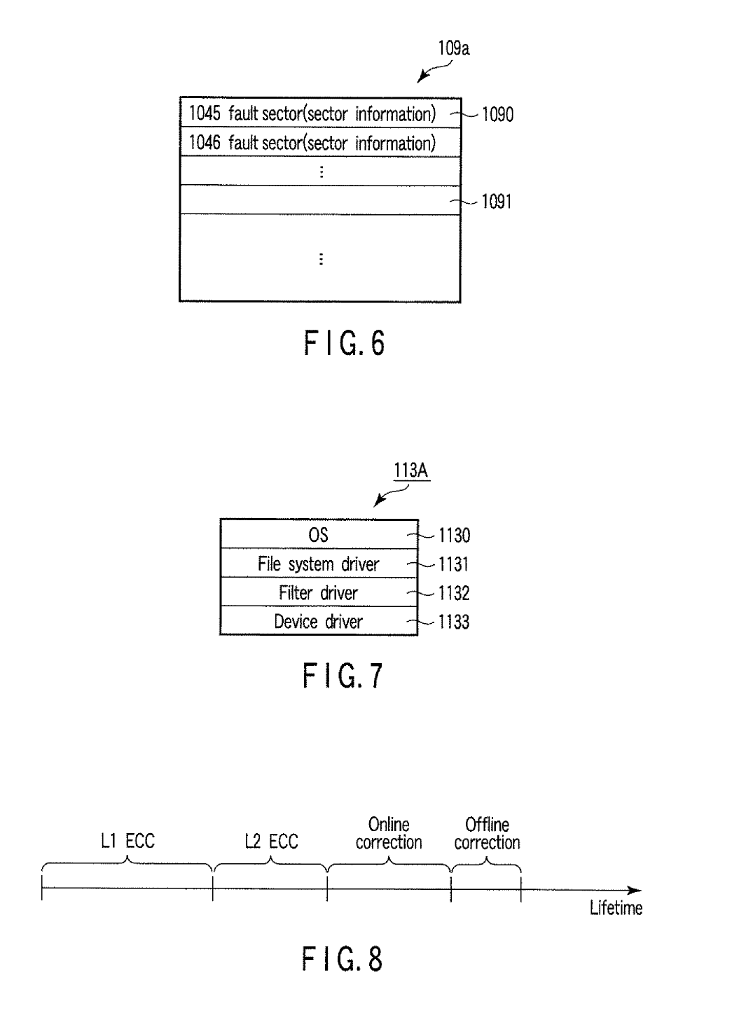

FIG. 6 is an exemplary schematic configuration view of a BCT of an embodiment of the invention. A BCT (management table) 109a is a table composed of a plurality of entries 1090. One entry 1090 consists of 5 byte in total of a cluster address (4 byte) and a bit map (1 byte) in a block 1040, and an extent of 4 K entry 1090 is secured so that the BCT 109a may operate even if a fault (error) of one sector 1042 (1 K cluster) occurs.

As an example shown in FIG. 6, two fault sectors (fault storage unit) 1045, 1046 are registered in the entry 1090 of the BCT 109a. The BCT 109a is created by the control unit 103 in refreshing the SSD 10 to be stored in the management data 107a. When a read error occurs in refreshing the SSD 10, the control unit 103 creates the BCT 109a.

The control unit 103, as shown in FIG. 5 or FIG. 6 as an example, registers the cluster 1041, including the fault sector 1045 where its error cannot be corrected by means of error correction processing or that is the read error in flashing, into the BCT 109a as a fault cluster 1044.

In the BCT 109a, as an example, it is assumed that the entry 1090 in which information of the fault sector has not been stored is referred to as a free entry 1091.

It is assumed that, as an example, when writing the data in the fault sectors 1045 and 1046 normally, the control unit 103 deletes the relevant entry 1090 in the BCT 109a.

This is because the fault sectors 1045, 1046 can normally read the data after the writing of the data is normally completed in a case in which the read error has been caused by missing of electric charges. Therefore, since the fault sectors 1045, 1046 are reutilized, original functions of the information processing apparatus 1 and the SSD 10 may be utilized for a long period.

(Hierarchical Structure of File System Driver)

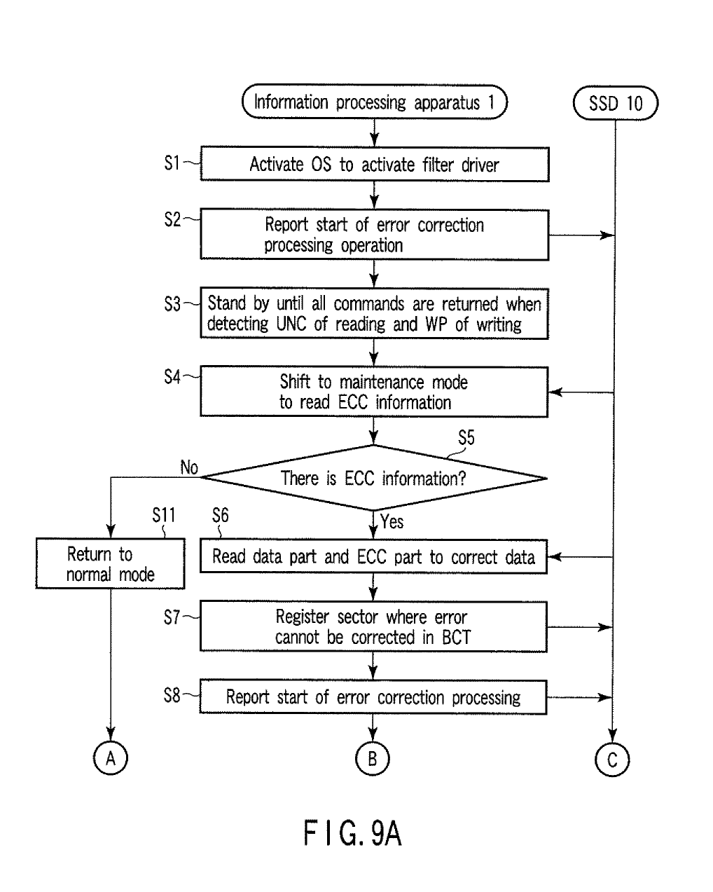

FIG. 7 is an exemplary schematic view showing a hierarchical structure of a file system driver of the embodiment of the invention When the information processing apparatus 1 is activated, an application 113A is read from the SSD 10 by means of the CPU 115 and stored in a cache of the south bridge 113 to be executed.

The application 113A includes an OS 1130, a file system driver 1131 managing a file system, a filter driver 1132 performing error correction processing to be referred to as an inter-page error check and correct (ECC), and a device driver 1133 operating a controller for writing data included in the file system in the SSD 10, for example.

The filter driver 1132 is positioned between the file system driver 1131 and the device driver 1133, and executed by the CPU 115 at the same time of the activation of the information processing apparatus 1.

The error correction processing for the data to be stored in the SSD 10 includes first error correction processing referred to as an L1ECC and an L2ECC and second error correction processing referred to as the inter-page ECC.

The L1ECC is an error correction processing to be performed in sectors 1042, performed by hardware (HW) built-in the SSD 10, and is suitable for a small-scale ECC error. The L2EEC is an error correction processing to be performed in clusters 1041, performed by firmware (FW) in the SSD 10, and is suitable for a middle-scale ECC error. That is, the SSD 10 itself performs the first error correction processing.

Meanwhile, the inter-page ECC that is the second error correction processing is performed by the information processing apparatus 1 in cooperation with the SSD 10 so as to meet a severe error of which the error cannot be corrected through the L1ECC and L2ECC, and the error correction processing by the inter-page ECC will be described in detail hereinafter.

The inter-page ECC is error correction processing which is executed, for example, in 1 M bytes (predetermined storage unit group), and is executed by software (SW) which has been activated by the information processing apparatus 1, and is appropriate to a large-scale ECC error. There are two kinds of error correction processing, i.e., an online correction and an offline correction.

The inter-page ECC may perform error correction processing including a redundant part of 32 K bytes per 1 M bytes. The redundant part means data to be stored other than a data main unit (data part) to be stored in the SSD 10, and stores the data related to the error correction processing therein.

The online correction is error correction processing to be performed in a case in which the information processing apparatus 1 may be activated from the SSD 10, and to be performed as the CPU 115 controls the filter driver 1132 shown in FIG. 7 when the error correction cannot be performed even the error correction processing through the L1ECC and L2ECC.

The offline correction is the error correction processing to be performed in a case in which the information processing apparatus 1 may not be activated from the SSD 10, and to be executed, for example, by activating the information processing apparatus 1 from an optical medium 270 shown in FIG. 2 and by activating the refresh tool 271 stored in the optical medium 270.

(Operation)

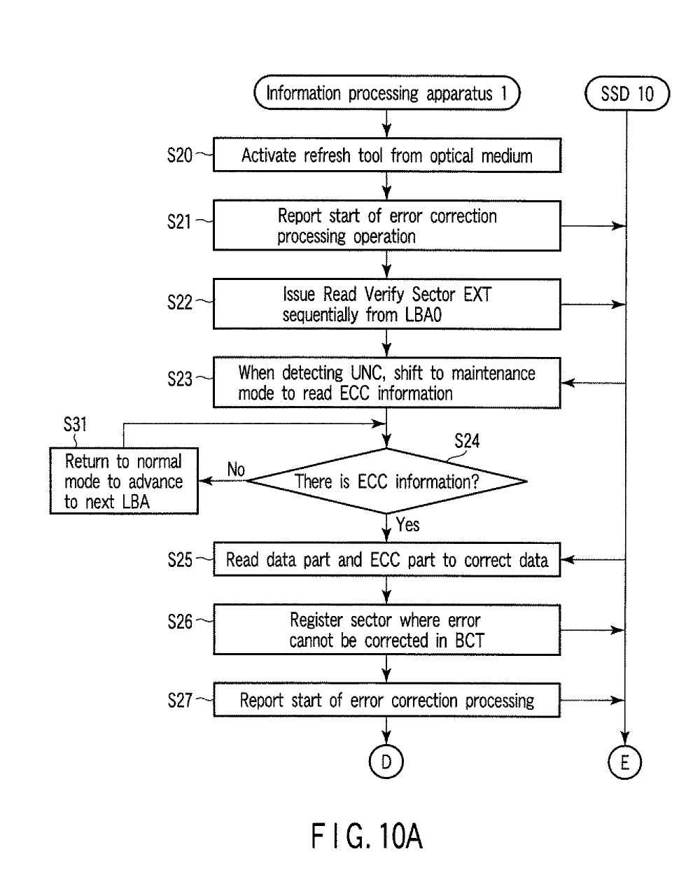

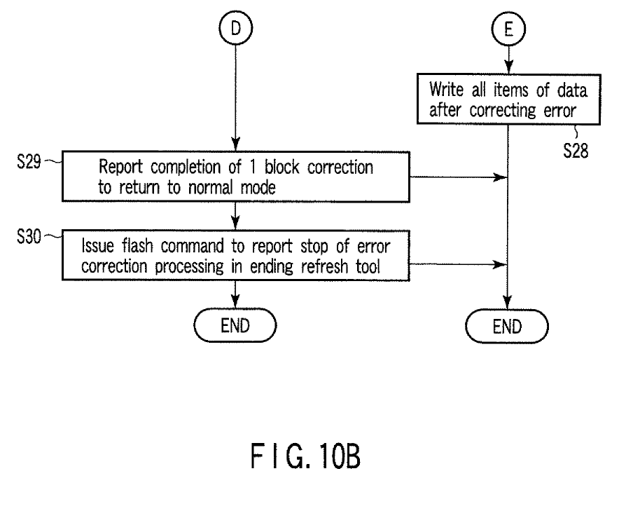

The following will describe operations of the information processing apparatus 1 of the embodiment of the invention in accordance with flowcharts of FIG. 9A, FIG. 9B, FIG. 10A and FIG. 10B with reference to each view.

(Online Correction Operation)

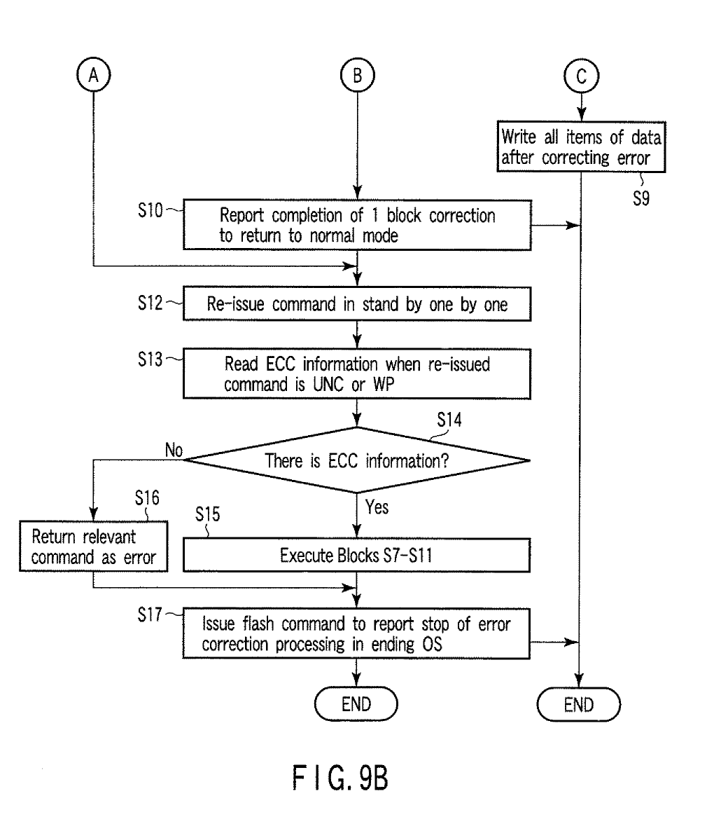

FIG. 8 is an exemplary schematic view in relation to a product lifetime of an SSD of the embodiment of the invention, and FIG. 9A and FIG. 9B are flowcharts in relation to online operations of the embodiment of the invention. The following will mainly describe control of operations of drivers, applications, etc., by the CPU 115 except operations to which descriptions are especially added in operations of the information processing apparatus 1.

Firstly, when a user presses the power switch 25, the EC 111, which has detected the depression of the power switch 25, starts to supply power to each components of the information processing apparatus 1. The EC 111 activates the information processing apparatus 1 on the basis of the BIOS 112a. With the activation of the information processing apparatus 1, the filter driver 1132 stored in the south bridge 113 is activated together with the OS 1130 (S1). When the filter driver 1132 has been activated, the CPU 115 of the information processing apparatus 1 reports the start of the error correction operation to the SSD 10 (S2).

When detecting an uncorrectable error (UNC) of reading or write protect (WP) of writing, the information processing apparatus 1 stands by until all the commands are returned (S3).

The UNC of the reading indicates that the read command of the file stored in the SSD 10 cannot correct the errors of the L1, L2 and poses an error for the SSD 10 from an external device connected to the information processing apparatus 1 via the network.

At this moment, the information processing apparatus 1 does not issue a command from a high-order layer to a low-order layer and stores it therein. This is equivalent, for example, to storing a command without issuing the command from the OS 1130, etc., to the low-order layer.

The information processing apparatus 1 then shifts to a maintenance mode to read the ECC information from the SSD 10 (S4). The maintenance mode means a mode for performing the error correction processing of the SSD 10 without receiving the command, and the inter-page ECC becomes able to operate only in the maintenance mode.

The ECC information means information based on the fault sector 1045 where the error cannot be corrected even by the error correction processing through the L1ECC and the L2ECC.

If there is the ECC information (Yes in S5), the information processing apparatus 1 reads the relevant data part (data main unit) and the ECC part (redundant part) from the NAND memories 104A-104H to execute the error correction processing (S6).

The information processing apparatus 1 registers the fault sector 1045 where the error cannot be corrected in the BCT 109a through the control unit 103 of the SSD 10 in Block 6 (S7). The information processing apparatus 1 then reports the start of the error correction processing to the SSD 10 (S8).

The firmware which has been executed by the control unit 103 of the SSD 10 receives the report, secures a RAM area for temporarily storing error-corrected data in the ROM 105 of 4 MB, and initializes the DRAM 105.

The control unit 103 reads the error-corrected data from the DRAM 105 to write the data in all the areas corresponding to the NAND memories 104A-104H (S9).

The information processing apparatus 1 reports the completion of the error correction processing of the one block 1040 to the SSD 10 to return to a normal mode from the maintenance mode (S10).

In Block S5, if there is no ECC information (No in S5), the information processing apparatus 1 returns from the maintenance mode to the normal mode (S11), and shifts to Block S12.

The information processing apparatus 1 which has returned to the normal mode in Block 10 re-issues commands, which have been in stand by, one by one (S12). The writing is assumed to be an operation equivalent to forced unit access (FUA) writing.

The FUA writing is a function of preventing data missing in power supply failure. The normal SSD 10 reports the completion of the write command at a time point when the data is written in the DRAM 105 of the SSD 10. Since the writing has not been performed in the NAND memories 104A-104H, if power interruption has occurred at this time point, the data in the DRAM 105 will be lost. Since in the FUA writing, the compression report is returned to the information processing apparatus 1 at the time point when the data has been written in the NAND memories 104A-104H, the possibility of data loss due to the power interruption may be reduced.

Next, the information processing apparatus 1 reads the ECC information when the re-issued command is the UNC or the WP (S13).

If there is the ECC information (Yes in S14), the information processing apparatus 1 executes Blocks S7-S11 (S15).

If there is no ECC information (No in S14), the information processing apparatus 1 returns the relevant command to the SSD 10 due to the occurrence of the error (S16).

When the operation stop of the information processing apparatus 1 is instructed through the operation by the user to stop the OS 1130, the information processing apparatus 1 issues a flash command to the SSD 10 then reports the completion of the error correction processing to the SSD 10 (S17).

The flash command means a command for instructing to write data which has not been written yet in the NAND memories 104A-104H.

(Offline Correction Operation)

FIG. 10A and FIG. 10B are exemplary flowcharts relevant to offline correction operations of the embodiment of the invention.

If the information processing apparatus 1 is in a state in which the OS of the information processing apparatus 1 may not be activated, the user presses the power switch 25 then inserts the optical medium 270 into the ODD 27. The activation program for activating the information processing apparatus 1 and the refresh tool 271 are recorded in the optical medium 270. When detecting the insertion of the optical medium 270, the ODD 27 reads the activation program and the refresh tool 271 recorded on the optical medium 270.

The EC 111 which has detected the press of the power switch 25 starts to supply power to each part of the information processing apparatus 1. The EC 111 activates the information processing apparatus 1 from the activation program recorded on the optical medium 270 on the basis of the BIOS 112a then activates the refresh tool 271 (S20). When the refresh tool 271 is activated, the CPU 115 of the information processing apparatus 1 reports the start of the error correction processing operation to the SSD 10 (S21).

The information processing apparatus 1 issues Read verify Sector EXTs sequentially from logical block addressing (LBA) 0 to the NAND memories 104A-104H of the SSD 10 (S22).

When detecting the UNC in the reading of the Read verify Sector EXTs, the information processing apparatus 1 shifts to the maintenance mode to read the ECC information from the SSD 10 (S23).

If there is the ECC information (Yes in S24), the information processing apparatus 1 reads the relevant data part and the ECC part to perform the error correction processing (S25).

The information processing apparatus 1 registers the fault sector 1045 where the error cannot be corrected in the BCT 109a through the control unit 103 in Block S25 (S26).

The information processing apparatus 1 then reports the start of the error correction processing to the SSD 10 (S27).

The firmware which has been executed by the control unit 103 of the SSD10 receives the report, secures the RAM area in which the error-corrected data is temporarily stored in the RAM 105 of 4 MB, and initializes the DRAM 105.

The control unit 103 reads the corrected data from the DRAM 105 to write to the areas corresponding to the NAND memories 104A-104H (S28).

The information processing apparatus 1 reports the end of the error correction processing of the one block 1042 to return from the maintenance mode to the normal mode (S29).

After ending the error correction processing, for terminating the refresh tool 271, the information processing apparatus 1 issues the flash command to the SSD 10 then reports the end of the error correction processing to the SSD 10 (S30).

If there is no ECC information in Block S24 (No in S24), the information processing apparatus 1 returns from the maintenance mode to the normal mode (S31), and advances the processing to Block S24 in order to retrieve whether or not there is the ECC information in the next LBA.

During execution of the inter-page ECC by the information processing apparatus 1, after reporting the error to the information processing apparatus 1 so as to correct the error, the firmware of the SSD 10 responds with an ABRT (abnormal end command) to a write system (write command), a read system (read command) and a command with flash which have received by the end of the error correction processing. However, the firmware normally responds to the command not related to the error correction processing. After ending the error correction processing through the filter driver 1132, the command which has been responded to through the ABRT is re-issued.

If the error is insignificant as shown in FIG. 8, the SSD 10 may extend the product lifetime through the error correction processing by the L1ECC and the L2ECC to be normally performed. However, if there is an error which cannot be corrected through the error correction processing by the L1ECC and the L2ECC, the information processing apparatus 1 capable of performing advanced error correction processing performs the online correction, and the offline correction then the information processing apparatus 1 may improve reliability and extend the product lifetime.

### EFFECT OF EMBODIMENT

According to the aforementioned embodiment, since the side of the information processing apparatus 1 may apply the error correction processing for the SSD 10 in addition to the error correction processing of the SSD 10, the reliability may be improved, and the product lifetime of the SSD 10 may be extended.

The various modules of the systems described herein can be implemented as software applications, hardware and/or software modules, or components on one or more computers, such as servers. While the various modules are illustrated separately, they may share some or all of the same underlying logic or code.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An information processing apparatus comprising:
an information processing apparatus main body; and
a non-volatile semiconductor memory drive which is accommodated in the information processing apparatus main body,
the information processing apparatus main body including a main control module configured to receive information including errors and error correction codes for correcting the errors included in the information from the non-volatile semiconductor memory drive, to correct the errors included in the information by using the error correction codes, and to return corrected information to the non-volatile semiconductor memory drive,
the non-volatile semiconductor memory drive including:
a non-volatile semiconductor memory including a plurality of storage areas where information is writable and information is readable; and
a memory control module configured to control execution of first error correction processing which corrects errors of the information stored in the storage areas for each sector and second error correction processing which corrects errors of the information stored in the storage areas for each cluster, to transmit information including the errors and error correction codes for correcting the errors included in the information to the information processing apparatus main body when errors which cannot be corrected by the first and the second error correction processing have occurred, and to update the information including the errors stored in the storage areas in the corrected information returned from the information processing apparatus main body.

2. The information processing apparatus of claim 1, wherein the non-volatile semiconductor memory of the non-volatile semiconductor memory drive is composed of a plurality of blocks, each of the blocks is composed of 1024 clusters, and each of the clusters includes 8 sectors.

3. The information processing apparatus of claim 1, wherein the memory control module of the non-volatile semiconductor memory drive responds with an answer indicating that processing of the command has abnormally ended, if the memory control module receives a command accompanied by access to the non-volatile semiconductor memory during a period starting at a time when the information including the errors and the error correction codes for correcting the errors included in the information are transmitted to the information processing apparatus main body and ending at a time when the corrected information is returned from the information processing apparatus main body.

4. A non-volatile semiconductor memory drive which is accommodated in an information processing apparatus main body, comprising:
a non-volatile semiconductor memory including a plurality of storage areas where information is writable and information is readable; and
a memory control module configured to control execution of first error correction processing which corrects errors of the information stored in the storage areas for each sector and second error correction processing which corrects errors of the information stored in the storage areas for each cluster, to transmit information including the errors and the error correction codes for correcting the errors included in the information to the information processing apparatus main body when errors which cannot be corrected by the first and the second error correction processing have occurred, and to update the information including the errors stored in the storage areas in the corrected information returned from the information processing apparatus main body.

5. The non-volatile semiconductor memory drive of claim 4, wherein the non-volatile semiconductor memory is composed of a plurality of blocks, each of the blocks is composed of 1024 clusters, and each of the clusters includes 8 sectors.

6. The non-volatile semiconductor memory drive of claim 4, wherein the memory control module responds with an answer indicating that processing of the command has abnormally ended, if the memory control module receives a command accompanied by access to the non-volatile semiconductor memory during a period starting at a time when the information including the errors and the error correction codes for correcting the errors included in the information are transmitted to the information processing apparatus main body and ending at a time when the corrected information is returned from the information processing apparatus main body.
